(19) United States
(12) Patent Application Publication
(10) Pub. No.: US 2024/0152670 A1
(43) Pub. Date: May 9, 2024

(54) INFORMATION PROCESSING APPARATUS, SIMULATOR SYSTEM, NEURAL NETWORK SYSTEM, ARGUMENT VALUE DETERMINATION METHOD, AND RECORDING MEDIUM

(71) Applicant: NEC Corporation, Minato-ku, tokyo (JP)

(72) Inventors: Keiichi Kisamori, Tokyo (JP); Yuto Komori, Tokyo (JP); Takashi Washio, Tokyo (JP)

(73) Assignee: NEC Corporation, Minato-ku, tokyo (JP)

(21) Appl. No.: 18/274,989

(22) PCT Filed: Feb. 2, 2022
(86) PCT No.: PCT/JP2022/004039

§ 371 Date: Jul. 28, 2023

(30) Foreign Application Priority Data
Feb. 3, 2021 (JP) 2021-016101

(51) Int. Cl. G06F 30/27

(52) U.S. Cl. CPC G06F 30/27

(57) ABSTRACT

An information processing device acquires, based on a set including a plurality of samples in which a first value and a second value are associated with each other, a first distribution that is a probability distribution of a first function for calculating the second value from the first value. The information processing device acquires, based on a second distribution having an average different from an average of each argument of the first function in the first distribution, a second function for calculating an evaluation value for an argument value of the first function. The information processing device determines, based on the evaluation value by the second function, an argument value for sampling a function value of the first function.

### TECHNICAL FIELD

This invention relates to an information processing device, a simulator system, a neural network system, an argument value determination method, and a recording medium.

### BACKGROUND ART

There may be cases where a function form is unknown, and if the argument value of the function is determined, the function value at that argument value can be observed, but the observation may be costly. In such cases, it is conceivable that an efficient search for an argument value that makes the function value as large as possible or the function value as small as possible is required.

For example, Patent Document 1 describes adjusting the value of each parameter so that the measurement sensitivity is as high as possible, using the applied voltage in a liquid chromatograph-mass spectrometer as a parameter. In addition, Patent Document 1 describes Bayesian optimization as one of the parameter search methods. Bayesian optimization uses the observed data to estimate the probability distribution of function values and determines the next observation point according to the estimated results. Then, the probability distribution of the function is re-estimated using the observation results, and the next observation point is repeatedly determined according to the estimation results.

### PRIOR ART DOCUMENTS

### Patent Documents

Patent Document 1: PCT International Publication No. WO2019/244474

### SUMMARY OF THE INVENTION

### Problems to be Solved by the Invention

When the probability distribution of a function value is estimated, as in Bayesian optimization, if the function value can be observed by preferentially selecting the argument value with which the function value can be maximized or the argument value with which the function value can be minimized, it is possible to efficiently search for the argument value that maximizes the function value or the argument value that minimizes the function value.

An example object of the present invention is to provide an information processing device, a simulator system, a neural network system, an argument value determination method, and a recording medium that can solve the above-mentioned problem.

### Means for Solving the Problem

According to a first example aspect of the invention, an information processing device includes: a probability distribution acquisition means that acquires, based on a set including a plurality of samples in which a first value and a second value are associated with each other, a first distribution that is a probability distribution of a first function for calculating the second value from the first value; a function acquisition means that acquires, based on a second distribution having an average different from an average of each argument of the first function in the first distribution, a second function for calculating an evaluation value for an argument value of the first function; and an argument value determination means that determines, based on the evaluation value by the second function, an argument value for sampling a function value of the first function.

According to a second example aspect of the invention, an argument value determination method executed by the computer includes: acquiring, based on a set including a plurality of samples in which a first value and a second value are associated with each other, a first distribution that is a probability distribution of a first function for calculating the second value from the first value; acquiring, based on a second distribution having an average different from an average of each argument of the first function in the first distribution, a second function for calculating an evaluation value for an argument value of the first function; and determining, based on the evaluation value by the second function, an argument value for sampling a function value of the first function.

According to a third example aspect of the invention, a recording medium stores a program for causing a computer to execute: acquiring, based on a set including a plurality of samples in which a first value and a second value are associated with each other, a first distribution that is a probability distribution of a first function for calculating the second value from the first value; acquiring, based on a second distribution having an average different from an average of each argument of the first function in the first distribution, a second function for calculating an evaluation value for an argument value of the first function; and determining, based on the evaluation value by the second function, an argument value for sampling a function value of the first function.

### Effect of Invention

According to an example embodiment of the present invention, a function value can be observed by preferentially selecting the argument value with which the function value can be maximized or the argument value with which the function value can be minimized.

### BRIEF DESCRIPTION OF THE DRAWINGS

FIG. 1 is a schematic block diagram showing the functional configuration of the observation system according to the example embodiment.

FIG. 2 is a diagram showing an example of the probability distribution of the objective function estimated by the probability distribution acquisition unit according to the example embodiment.

FIG. 3 is a flowchart showing an example of a processing procedure in which the information processing device of the example embodiment estimates a global optimal solution of an objective function.

FIG. 4 is a diagram showing an example of the characteristics of the evaluation function according to the example embodiment.

FIG. 5 is a diagram showing an example of a Forrester function.

FIG. 6 is a diagram showing an example of the transition of the estimation results of the minimum value of the Forrester function when EI is used.

FIG. 7 is a diagram showing an example of the transition of the estimation results of the minimum value of the Forrester function when using the Gumbel EI according to the present example embodiment.

FIG. 8 is a diagram showing an example of the estimation results of the minimum value of the Forrester function for EI and Gumbel EI.

FIG. 9 is a diagram showing an example of the transition of the estimation results of the minimum value of the Forrester function when the UCB is used.

FIG. 10 is a diagram showing an example of the transition of the estimation results of the minimum value of the Forrester function when using the Gumbel CB according to the example embodiment.

FIG. 11 is a diagram showing an example of the estimation results of the minimum value of the Forrester function for UCB and Gumbel CB.

FIG. 12 is a diagram showing an example of an alpine function.

FIG. 13 is a diagram showing an example of the transition of the estimation results of the minimum value of the alpine function when EI is used.

FIG. 14 is a diagram showing an example of the transition of the estimation results of the minimum value of the alpine function when using Gumbel EI according to the example embodiment.

FIG. 15 is a diagram showing an example of the estimation results of the minimum value of the alpine function for EI and Gumbel EI.

FIG. 16 is a diagram showing an example of the transition of the estimation results of the minimum value of the alpine function when UCB is used.

FIG. 17 is a diagram showing an example of the transition of the estimation results of the minimum value of the alpine function when using the Gumbel CB according to the example embodiment.

FIG. 18 is a diagram showing an example of the estimation results of the minimum value of the alpine function for UCB and Gumbel CB.

FIG. 19 is a diagram showing a configuration example of the information processing device according to the example embodiment.

FIG. 20 is a diagram showing a configuration example of a simulator system according to the example embodiment.

FIG. 21 is a diagram showing a configuration example of a mixing ratio determination system according to the example embodiment.

FIG. 22 is a diagram showing a configuration example of a neural network system according to the example embodiment.

FIG. 23 is a flowchart showing an example of the processing procedure in the argument value determination method according to the example embodiment.

FIG. 24 is a schematic block diagram of a computer for at least one example embodiment.

### EXAMPLE EMBODIMENT

Example embodiments of the present invention will be described below, but the following example embodiments do not limit the invention according to the claims. All of the combinations of features described in the example embodiment may not be essential to the solution of the invention.

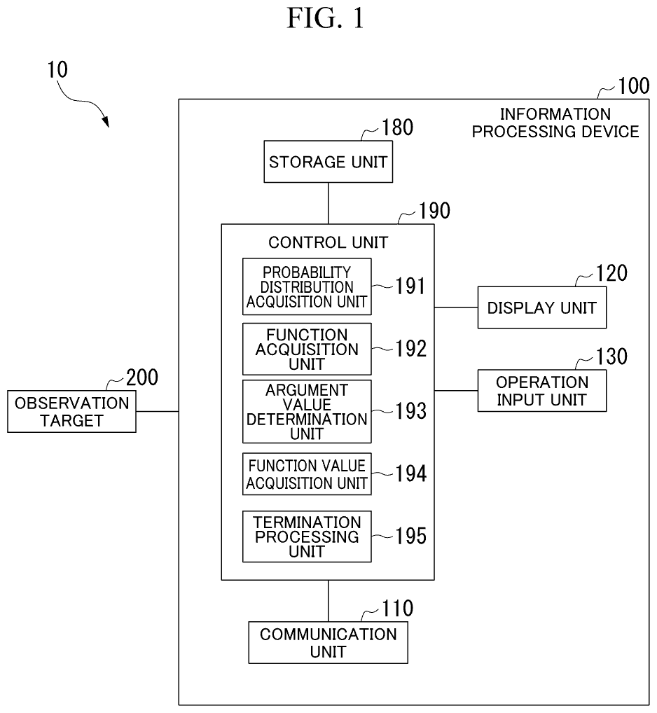

FIG. 1 is a schematic block diagram showing the functional configuration of an observation system 10 according to the example embodiment. In the configuration shown in FIG. 1, the observation system 10 includes an information processing device 100 and an observation target 200. The information processing device 100 includes a communication unit 110, a display unit 120, an operation input unit 130, a storage unit 180S, and a control unit 190. The control unit 190 includes a probability distribution acquisition unit 191, a function acquisition unit 192, an argument value determination unit 193, a function value acquisition unit 194, and a termination processing unit 195.

The observation system 10 observes a function related to the observation target 200, and estimates the argument value at which the value of this function is a maximum, or estimates the maximum value of the function. Alternatively, the observation system 10 may observe a function related to the observation target 200 and estimate the argument value at which the value of the function is a minimum, or estimate the minimum value of the function.

Here, observing a function means setting the argument value of the function and acquiring the value of the function in the case of that argument value. Observing a function is also referred to as sampling the function value. The function value obtained by the observation may contain noise.

The function related to the observation target 200, which is the object of observation by the observation system 10, is called the objective function. The argument value at which the value of the objective function takes its maximum value and the argument value at which the value of the objective function takes its minimum value are also collectively referred to as the global optimal solution. The maximum and minimum values of the objective function are also collectively denoted as the global extrema.

The objective function can be various functions that are capable of being observed and are capable of estimating, based on the observation results, the probability distribution of the value of the function for argument values other than argument values whose function value was observed. The argument of the objective function may be a scalar or a vector. That is, the objective function may be a single-variable function or a multivariable function. The observation target 200 can be a variety of things for which the objective function is defined.

The argument value subject to observation for the objective function and the function value obtained from the observation respectively correspond to an example of the first value and second value. As discussed above for the argument values of the objective function, the first value may be a scalar or a vector. A combination of an argument value and an objective function value in the objective function observation result corresponds to an example of a sample in which the first and second values are associated with each other.

The objective function, or a function in which noise is superimposed on the objective function, is an example of the first function.

For example, the observation target 200 may be a system, simulator, or an apparatus with parameters. The objective function may then be a function that receives the input of parameter values and outputs an evaluation value of the result of the operation of the observation target 200. The observation system 10 may estimate the parameter value that gives the highest evaluation of the operation result of the observation target 200.

Here, it is conceivable that, while the entire objective function is unknown, the objective function can be observed, such as when the observation target 200 needs to be actually operated in order to obtain the evaluation value.

Therefore, the observation system 10 estimates the parameter value that maximizes the evaluation value of the operation result of the observation target 200 based on the observation result of the objective function. The observation system 10 may perform multiple observations of the objective function and output the parameter value at the time of the observation with the highest objective function value as the parameter value of the estimation result. Alternatively, the observation system 10 may linearly approximate the objective function based on the observation results of the objective function and output the argument value that maximizes the value of the obtained approximation formula as the parameter value of the estimation result.

Since the parameter values obtained by the observation system 10 is not necessarily the actual optimal solution, it is denoted as “estimated”. The “optimal solution” here refers to the parameter value at which the evaluated value of the operation result of the observation target 200 is the maximum value.

The information processing device 100 observes the objective function and estimates the global optimal solution or the global extrema as described above for the observation system 10. The information processing device 100 may be configured using a computer, such as a personal computer (PC) or workstation (WS).

The communication unit 110 communicates with other devices. For example, the communication unit 110 may transmit parameter values to the observation target 200 to set the parameter values to the observation target 200. Additionally, for example, the communication unit 110 may send parameter values for the observation of the objective function to the observation target 200. The communication unit 110 may transmit the parameter values estimated by the information processing device 100 as the global optimal solution to the observation target 200. The communication unit 110 may receive sensor measurement data used as the objective function value or sensor measurement data for calculating the objective function value from a sensor installed in the observation target 200.

The display unit 120 has a display screen, such as a liquid crystal panel or LED (Light Emitting Diode) panel, for example, and displays various images. For example, the display unit 120 may display the observation status of the objective function, such as by displaying the probability distribution of the value of the objective function and the coordinates of the argument and function values of the observed results of the objective function on a graph. The display unit 120 may also display the estimation results of the global optimal solution or the global extrema.

If the argument value calculated by the information processing device 100 indicates a manually set amount for the observation target 200, the display unit 120 may display the argument value. For example, if the observation target 200 is a production device for a certain item, and the argument value of the objective function indicates the amount of each material that should be manually fed into the observation target 200, the display unit 120 may display the amount of each material. The user may refer to the argument values displayed by the display unit 120 to perform settings on the observation target 200.

The operation input unit 130 has input devices such as a keyboard and mouse, for example, and receives user operations. For example, the operation input unit 130 may receive a user operation that instructs the information processing device 100 to start the global optimal solution estimation process.

The storage unit 180 stores various data. For example, the storage unit 180 stores historical information on the observation results of the objective function. The storage unit 180 is configured using a storage device provided by the information processing device 100.

The control unit 190 controls each part of the information processing device 100 to perform various processing. The functions of the control unit 190 are performed, for example, by the CPU (Central Processing Unit) included in the information processing device 100, which reads and executes a program from the storage unit 180.

The probability distribution acquisition unit 191 estimates the probability distribution of the objective function based on the observation results of the objective function. The probability distribution of a function is the probability distribution of the function value at that argument value, for each argument value. The probability distribution acquisition unit 191 corresponds to an example of a probability distribution acquisition means. The probability distribution of the objective function acquired by the probability distribution acquisition unit 191 corresponds to an example of the first distribution.

The probability distribution acquisition unit 191 may estimate the probability distribution of the objective function by Gaussian Process Regression.

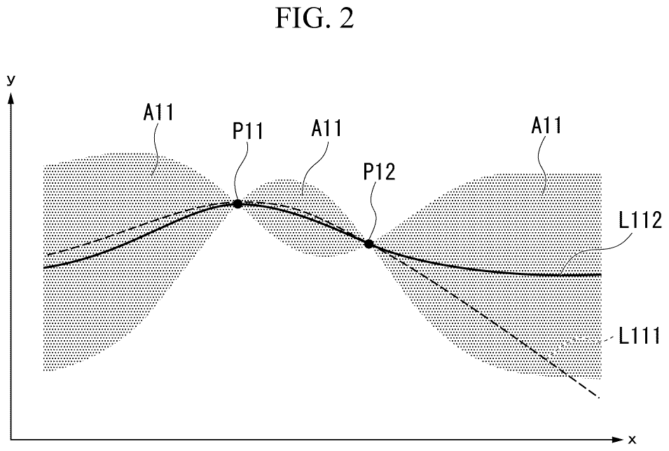

FIG. 2 is a diagram that shows an example of the probability distribution of the objective function estimated by the probability distribution acquisition unit 191. The horizontal axis of the graph in FIG. 2 represents the argument value of the objective function, while the vertical axis represents the value of the objective function. The argument value is represented by x, and the objective function value is represented by y.

Line L111 represents the true objective function. However, the true objective function is unknown to the probability distribution acquisition unit 191.

Points P11 and P12 indicate the measurement results of the objective function. In the example in FIG. 2, the probability distribution acquisition unit 191 estimates the probability distribution of the objective function based on the measurement results represented by points P11 and P12. As mentioned above, the estimation result of the objective function may contain noise. Thus, the observation result may deviate from the true objective function.

Line L112 shows an example of the mean in the probability distribution estimated by the probability distribution acquisition unit 191. Region A11 shows an example of a 95 percent confidence interval in the probability distribution estimated by the probability distribution acquisition unit 191.

The probability distribution acquisition unit 191 may estimate the probability distribution of the objective function by calculating the mean and variance of the objective function as function having arguments of the objective function as arguments, respectively.

The function acquisition unit 192 acquires a function for determining the argument values of the observation target of the objective function. Specifically, the function acquisition unit 192 acquires a function that receives an input of an argument value for the objective function and outputs an evaluation value for that argument value. The evaluation value for an argument value here is the evaluation value that indicates the priority of performing observation of the objective function for that argument value. The function acquired by the function acquisition unit 192 is also referred to as an evaluation function. This evaluation function is an example of the second function. The function acquisition unit 192 is an example of a function acquisition means.

The argument value to be observed for the objective function is also referred to as an observation point of the objective function or simply an observation point.

The information processing device 100 may use Bayesian optimization to estimate a global optimal solution.

Bayesian optimization is one method of estimating the maximum or minimum value of a function. Here, the function for which the maximum or minimum value is to be estimated in Bayesian optimization is referred to as the objective function.

In Bayesian optimization, the probability distribution of the objective function is estimated by applying Gaussian process regression to the observation results of the objective function, and a function called the acquisition function is set based on the estimation results. In Bayesian optimization, the value of the objective function is observed for the argument value that maximizes the value of the acquisition function, the probability distribution of the objective function is re-estimated based on the observation results, and the acquisition function is updated. In Bayesian optimization, the objective function is repeatedly observed in this manner to estimate the maximum or minimum value of the objective function.

When the information processing device 100 estimates a global optimal solution by Bayesian optimization, the evaluation function calculated by the function acquisition unit 192 corresponds to an acquisition function.

Probability of Improvement (PI), Expected Improvement (EI), and Upper Confidence Bound (UCB) have been proposed as acquisition functions in Bayesian optimization.

The acquisition function PI is shown in Equation (1).

[Equation 1]

α_{PI}(xₜ)=Pᵣ{f(xₜ)−y_{b}≥0} (1)

Here, the acquisition function PI is denoted as α_{PI}(*) on the left-hand side of Equation (1).

Since the acquisition function is updated with each observation of the objective function as described above, time is represented by the number of observations conducted. “xₜ” indicates the argument value to be obtained at time t. Therefore, “xₜ” indicates the argument value at which the objective function should be observed at the (t+1)-th observation.

f(*) denotes the objective function. f(xₜ) denotes the objective function value obtained at the (t+1)-th observation. Here, it is assumed that there is no noise superimposed on the objective function value obtained from the observation.

y_{b} represents the optimal value of the objective function observed so far. Here, an example is shown for estimating the maximum value of the objective function. Where y_{b} represents the maximum value among the observed objective function values. This y_{b} is used as an estimate of the maximum value of the objective function at that point in time (time t). Pᵣ{*} indicates the probability that the event in braces ({ }) will occur. Pᵣ{f(xₜ)−y_{b}≥0} indicates the probability that “f(xₜ)−y_{b}≥0” is satisfied. Therefore, in Bayesian optimization using PI, the argument value with the highest probability that the estimated value of the maximum value of the objective function is improved by the observation is selected as the argument value at which the objective function should be observed next.

The acquisition function PI is specifically shown in Equation (2).

[Equation 2]

α_{PI}(xₜ)=F_{0,1}(r(xₜ)) (2)

F_{0,1}(*) denotes the Cumulative Distribution Function (CDF) of the standard normal distribution.

r(*) is shown in Equation (3).

$$\begin{matrix}[ Equation 3 ] & \\ r ( x ) = \frac{{μ}_{t} ( x ) - {y}_{b}}{{σ}_{t} ( x )} & ( 3 )\end{matrix}$$

μₜ(x) is a function that represents the mean of the probability distribution of the estimated value of the objective function at time t. σₜ(X) is a function that represents the standard deviation of the probability distribution of the estimated value of the objective function at time t.

The acquisition function EI is shown in Equation (4).

[Equation 4]

α_{EI}(xₜ)=E_{f(x}_{ₜ}_{)˜N(μ}_{ₜ}_{,σ}_{ₜ}₎[max (f(xₜ)−y_{b}, 0)] (4)

Here, the acquisition function EI is denoted as α_{EI}(*) as shown on the left-hand side of Equation (4).

E denotes the expected value under the conditions indicated by the subscript. μₜ and σₜ denote the mean and standard deviation of the probability distribution of the estimated value of the objective function at time t, respectively. N(μₜ, σₜ) denotes the normal distribution as the probability distribution of the estimated value of the objective function at time t. max(*) is the function that outputs the maximum value among the arguments. Thus, the right-hand side of Equation (4) indicates the expected value of improvement in the estimate of the maximum value of the objective function at the next observation.

Therefore, in Bayesian optimization using EI, the argument value with the largest expected value of improvement in the estimate of the maximum value of the objective function at that observation is selected as the next argument value that should be used to observe the objective function.

The acquisition function EI is specifically shown in Equation (5).

[Equation 5]

α_{EI}(xₜ)=(μₜ(xₜ)−y_{b})F_{0,1}(r(xₜ))+σₜ(xₜ)φ(r(xₜ)) (5)

φ(*) is shown in Equation (6).

[Equation 6]

φ(*)=N(0,1) (6)

N(0, 1) denotes the standard normal distribution.

The acquisition function UCB is shown in Equation (7).

[Equation 7]

α_{UCB}(x)=μₜ₋₁(x)+k_{UCB}σₜ₋₁(x) (7)

k_{UCB} is a coefficient that adjusts the weight of the mean μₜ₋₁(x) and standard deviation σₜ₋₁(x) of the probability distribution of the estimated value of the objective function.

If the region D is a finite region, the coefficient k_{UCB} may be set as in Equation (8).

[Equation 8]

k_{UCB}=\sqrt{2ln |D|t²π²/6δ} (8)

In denotes the natural logarithm.

|D| indicates the size of the region D.

π denotes pi.

δ denotes a constant that satisfies “0<δ<1”.

If d is a positive integer and the region D is a compact region that is a subregion of the d-dimensional region [0, r]^{d}, the coefficient k_{UCB} may be set as in Equation (9).

[Equation 9]

k_{UCB}={square root over (2ln (t²2π²/3δ)+2dln (t²dbr\sqrt{ln(4da/δ)}))} (9)

a is a constant that satisfies “a>0”. b is a constant that satisfies “b>0”.

The above-mentioned PI, EI, and UCB are all based on the normal distribution that represents the probability distribution of the objective function. For example, PI is based on the cumulative distribution function F_{0,1}(*) of the standard normal distribution, as shown in Equation (2). EI is based on φ(*), which represents the standard normal distribution, as shown in Equations (5) and (6). UCB is based on the standard deviation σₜ₋₁(*) of the normal distribution, as shown in Equation (7).

In contrast, the function acquisition unit 192 acquires, as the above evaluation function, an evaluation function based on a distribution with a mean that is different from the mean for each argument in the probability distribution of the objective function.

By the function acquisition unit 192 acquiring an evaluation function using such a distribution, the information processing device 100 can determine the next observation point with more emphasis on the possibility of obtaining a global optimal solution than when using a function based on the probability distribution of the objective function.

The function acquisition unit 192 may acquire an evaluation function based on an extreme value distribution that is based on the probability distribution of the objective function. The extreme value distribution is a distribution of samples that are larger than a given condition or smaller than a given condition among a given number of samples that follow an independent and identically distributed (i.i.d.) pattern.

Among extreme value distributions, a distribution of samples larger than a given condition is also called a maximum value distribution. Among extreme value distributions, a distribution of samples smaller than a given condition is also called a minimum value distribution. When estimating the maximum value of the objective function, the information processing device 100 may use an evaluation function based on the maximum value distribution. When estimating the minimum value of the objective function, the information processing device 100 may use an evaluation function based on the minimum value distribution.

The cumulative distribution function of the maximum value distribution is shown in Equation (10).

$$\begin{matrix}[ Equation 10 ] & \\ F ( x ; μ , θ , γ ) = exp [ - {\{ 1 + γ ( \frac{x - μ}{θ} ) \}}^{- 1 / γ} ] & ( 10 )\end{matrix}$$

μ, θ, and γ are all real parameters. θ satisfies the condition “θ>0”. In addition, the condition “1+γ(x−μ)/θ>0” is satisfied. The “/” represents the division operator.

The cumulative distribution function of the minimum value distribution is expressed as “1−F(−x)”.

The function acquisition unit 192 may acquire an evaluation function based on the Gumbel distribution, which is based on the probability distribution of the objective function. The Gumbel distribution is the distribution of the largest sample or the smallest sample among a given number of samples that follow an independent and identical distribution. The Gumbel distribution is a type of extreme value distribution. The following explanation will use the Gumbel distribution as an example, but the process of obtaining the evaluation function is not limited to using the Gumbel distribution or the extreme value distribution. The process of obtaining the evaluation function may be, for example, a process using the distribution of the second-largest sample among N (where N≥4) samples, or the distribution of the third-largest sample out of M (where M≥6) samples. In other words, the process of acquiring the evaluation function may be a process that uses a distribution in which the average in the distribution of samples is different from the average in the extracted samples.

Let m samples {y₁, . . . , yₘ} be independent and identically distributed samples generated from the normal distribution N (μ, σ), with the maximum value of these samples denoted as y⁺. In this case, the cumulative distribution function F_{G}(y⁺) in the Gumbel distribution is expressed as shown in Equation (11).

$$\begin{matrix}[ Equation 11 ] & \\ {F}_{G} ( {y}^{+} ) = exp [ - exp \{ - \frac{{y}^{+} - {μ}_{G}}{{σ}_{G}} \} ] & ( 11 )\end{matrix}$$

exp indicates an exponential function whose base is the Napier number e, i.e., a power of e.

μ_{G} is the mean in the Gumbel distribution and is expressed as shown in Equation (12).

$$\begin{matrix}[ Equation 12 ] & \\ {μ}_{G} = {F}_{μ , G}^{- 1} ( 1 - \frac{1}{m} ) & ( 12 )\end{matrix}$$

F_{μ,σ}⁻¹(*) denotes a quantile function in a normal distribution with the mean of μ and the standard deviation of σ.

σ_{G} is the standard deviation in the Gumbel distribution and is shown in Equation (13).

$$\begin{matrix}[ Equation 13 ] & \\ {σ}_{G} = {F}_{μ , σ}^{- 1} ( 1 - \frac{1}{em} ) - {μ}_{G} ( x ) & ( 13 )\end{matrix}$$

e represents the Napier number.

μ_{G}(x) denotes the average μ_{G} shown in Equation (12).

The probability density function in the Gumbel distribution is expressed as in Equation (14).

$$\begin{matrix}[ Equation 14 ] & \\ {f}_{G} ( {y}^{+} ) = \frac{1}{{σ}_{G}} exp \{ - \frac{{y}^{+} - {μ}_{G}}{{σ}_{G}} ) \times exp [ - exp \{ - \frac{{y}^{+} - {μ}_{G}}{{σ}_{G}} \} ] & ( 14 )\end{matrix}$$

The function acquisition unit 192 may calculate an evaluation function using Equation (15).

[Equation 15]

α_{GPI}(xₜ)=1−F_{G}(y_{b}) (15)

Equation (15) treats the mean μ_{G} and standard deviation σ_{G} in the Gumbel distribution as a function of xₜ.

By substituting the maximum value of the objective function value in the observation of the objective function up to that point for y_{b} on the right-hand side of Equation (15), an evaluation function can be obtained. This evaluation function is also referred to as Gumbel PI.

Also, if the normal distribution N(μₜ, σₜ) on the right-hand side of Equation (4) is replaced with the probability density function f_{G}(y+) of the Gumbel distribution shown in Equation (14), the function α_{GEI}(xt) shown in Equation (16) is obtained.

[Equation 16]

α_{GEI}(xₜ)=E_{f(x}_{ₜ}_{)˜f}_{_{G}}[max (f(xₜ)−y_{b}, 0)] (16)

f_{G} in Equation (16) denotes f_{G}(y⁺).

α_{GEI}(xₜ) is expressed as shown in Equation (17).

[Equation 17]

α_{GEI}(xₜ)=μ_{G}(xₜ)−y_{b}+σ_{G}(xₜ)(γ+E₁(s_{b})) (17)

γ denotes the Euler-Mascheroni constant.

s_{b} is expressed as shown in Equation (18).

$$\begin{matrix}[ Equation 18 ] & \\ {s}_{b} = exp \{ - \frac{{y}_{b} - {μ}_{G} ( {x}_{t} )}{{σ}_{G} ( {x}_{t} )} \} & ( 18 )\end{matrix}$$

E₁(*) is expressed as shown in Equation (19).

$$\begin{matrix}[ Equation 19 ] & \\ \begin{matrix}Ei ( z ) = - {\int }_{- z}^{∞} {e}^{- t} / tdt \\ - {E}_{1} ( z ) = Ei ( - z )\end{matrix} \} & ( 19 )\end{matrix}$$

The function acquisition unit 192 may use Equations (17) through (19) to calculate the evaluation function. By substituting the maximum value of the objective function value in the observation of the objective function up to that point in time into y_{b} in Equations (17) and (18), the evaluation function can be obtained. This evaluation function is also referred to as Gumbel EI.

The function acquisition unit 192 may calculate the evaluation function using Equation (20).

$$\begin{matrix}[ Equation 20 ] & \\ \begin{matrix}{α}_{GCB} ( x ) = {F}^{- 1} ( 1 - δ ) \\ = {μ}_{G} ( x ) - {σ}_{G} ( x ) ln ln \frac{1}{1 - δ}\end{matrix} & ( 20 )\end{matrix}$$

As mentioned above, δ denotes a constant that satisfies “0<δ<1”.

The evaluation function based on Equation (20) is also referred to as Gumbel CB.

The argument value determination unit 193 determines the next observation point using the evaluation function calculated by the function acquisition unit 192. The next observation point is the argument value at which the next observation of the objective function should be made.

Specifically, the argument value determination unit 193 determines the argument value at which the evaluation function calculated by the function acquisition unit 192 is maximized as the next observation point.

The argument value determination unit 193 corresponds to an example of an argument value determination means.

The function value acquisition unit 194 acquires the objective function value by observing the objective function for the observation point determined by the argument value determination unit 193. For example, the function value acquisition unit 194 sets the argument value determined by the argument value determination unit 193 to the observation target 200 by transmitting this argument value to the observation target 200 via the communication unit 110. Then, the argument value determination unit 193 receives sensor measurement data corresponding to the objective function value in the case of the argument value set for the observation target 200 from the observation target 200 via the communication unit 110.

The termination processing unit 195 performs processing when the estimation of the global optimal solution by the information processing device 100 is completed. For example, the termination processing unit 195 determines whether the condition for terminating the observation of the objective function is satisfied. If the termination condition is determined to be satisfied, the termination processing unit 195 outputs the estimation result of the objective function value.

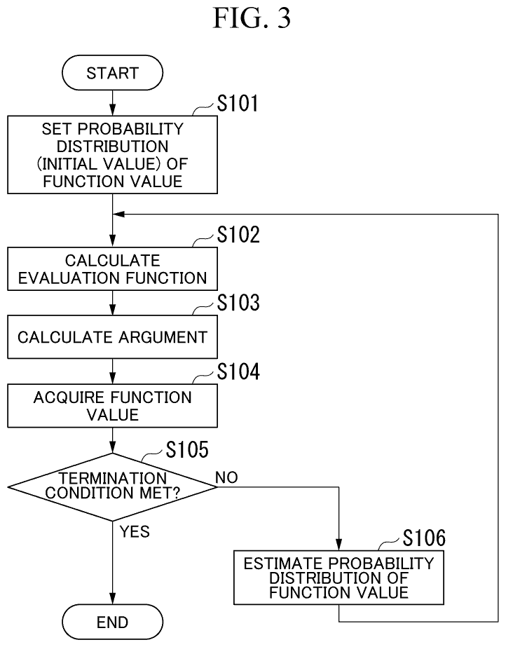

FIG. 3 is a flowchart showing an example of a processing procedure in which the information processing device 100 estimates a global optical solution of the objective function. The information processing device 100, for example, starts the process shown in FIG. 3 when the operation input unit 130 receives a user operation instructing the estimation of a global optimal solution.

In the process shown in FIG. 3, the probability distribution acquisition unit 191 sets the initial value for the probability distribution of the objective function (Step S101). For example, the function value acquisition unit 194 may observe the objective function for predetermined argument values, and the probability distribution acquisition unit 191 may estimate the probability distribution of the objective function based on the observation results. Alternatively, the probability distribution acquisition unit 191 may set a predetermined probability distribution as the initial value of the probability distribution of the objective function.

Next, the function acquisition unit 192 calculates the evaluation function (Step S102). For example, the function acquisition unit 192 may calculate the evaluation function by substituting the observation results, such as the maximum value of the objective function value among the observation results at that time, into a template of the evaluation function.

Next, the argument value determination unit 193 calculates the next observation point using the evaluation function calculated by the function acquisition unit 192 (Step S103). For example, the argument value determination unit 193 calculates the argument value that maximizes the evaluation function as the next observation point.

Next, the function value acquisition unit 194 observes the objective function for the observation point calculated by the argument value determination unit 193 and acquires the objective function value of the observation result (Step S104).

Next, the termination processing unit 195 determines whether the condition for terminating the repetition of observation has been met (Step S105). The condition for terminating the repetition of observation is not limited to a specific condition. For example, the condition for terminating the repetition of observation may be that the observation has been performed a predetermined number of times.

Alternatively, the condition for ending the repetition of observation may be that the magnitude (absolute value) of the change in the estimate of the global extremes due to repeated observations is smaller than a predetermined magnitude. When the information processing device 100 estimates the argument value at which the objective function takes a maximum value, the condition for terminating repetition of the observation may be that “the maximum value of the observed objective function does not increase from the previous observation, for a predetermined number of consecutive occurrences or more”. When the information processing device 100 estimates the argument value at which the objective function takes a minimum value, the condition for terminating repetition of the observation may be that “the minimum value of the observed objective function does not decrease from the previous observation, for a predetermined number of consecutive occurrences or more”.

If the termination processing unit 195 determines that the termination condition has not been met (Step S105: NO), the probability distribution acquisition unit 191 estimates the probability distribution of the objective function based on the history of observation results of the objective function (Step S106). In this case, the probability distribution acquisition unit 191 updates the probability distribution of the objective function.

After Step S106, the process transitions to Step S102.

On the other hand, if the termination processing unit 195 determines that the termination condition has not been met (Step S105: YES), the information processing device 100 terminates the process in FIG. 3. In this case, the termination processing unit 195 may output an estimated value of the global optimal solution for the objective function value. For example, the termination processing unit 195 may display an estimated value of the global optimal solution of the objective function value on the display unit 120. Alternatively, the termination processing unit 195 may transmit the estimated value of the global optimal solution of the objective function value to the observation target 200 via the communication unit 110.

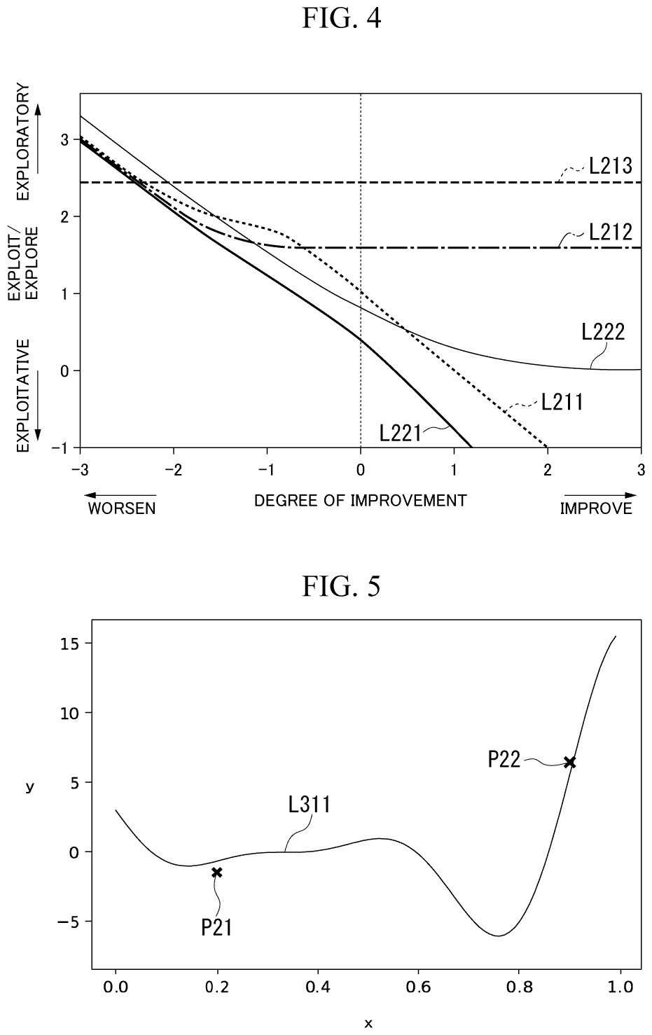

FIG. 4 is a diagram showing an example of the characteristics of the evaluation function. The horizontal axis of the graph in FIG. 4 shows an index value of the degree of improvement in the estimated value of the global extremes of the objective function. The vertical axis shows the index value of whether the observation of the objective function is exploratory or exploitative. FIG. 4 shows an example of analysis for the case where the information processing device 100 estimates the minimum value of the objective function.

Line L211 shows an example of the analysis result for Gumbel PI. Line L212 shows an example of the analysis result for Gumbel EI. Line L213 shows an example of the analysis result for Gumbel CB.

Line L221 shows an example of the analysis result for PI. Line L222 shows an example of the analysis result for EI. For comparison with the evaluation function, these acquisition functions are analyzed in the same manner as the evaluation function.

The degree of improvement in the estimated value of the global extreme values of the objective function indicates how close or far the estimates of the global extreme values by the information processing device 100 are from the actual global extreme values.

In FIG. 4, “r=(μ−f_{b})/σ” is shown on the horizontal axis as an index value of the degree of improvement in the estimated value of the global extreme values of the objective function. As shown in the equation, this index value r is a normalized value obtained by dividing the difference obtained by subtracting the minimum value f_{b} of the objective function value in the previous observation from the mean μ of the prediction value of the objective function by the standard deviation σ of the probability distribution of the prediction value of the objective function.

Exploitative here means that the next observation point is determined by focusing on the objective function value estimated from the observation result of the objective function. Exploratory here means that the next observation point is determined by focusing on the possibility of improving the estimate of the global extreme values rather than the objective function value estimated from the observation result of the objective function.

In the example in FIG. 4, where the evaluation function is in a form including a term based on the mean μ of the probability distribution of the estimated value of the objective function and a term based on the standard deviation σ, a comparison of the magnitude of the coefficient of each term is used as an index value to indicate whether the function is exploitative or exploratory.

The mean μ of the probability distribution of the estimated values of the objective function can be thought of as coordinates obtained by linearly approximating the coordinates of the observation results. Therefore, increasing the coefficient of this mean μ term can be said to be exploitative, which emphasizes the objective function value estimated from the observation results of the objective function.

On the other hand, when the standard deviation σ is large, the variation in the estimated value of the objective function is large. Therefore, increasing the coefficient on this standard deviation σ term can be said to be exploratory, emphasizing the possibility of improving the estimated value of the global extreme values.

Looking at FIG. 4 in the direction of the vertical axis and comparing line L211 and line L221, line L211 is higher than line L221. Accordingly, comparing Gumbel PI shown by line L211 with PI shown by line L221, it can be said that Gumbel PI is more exploratory than PI when the same degree of improvement is obtained.

In the comparison between line L212 and line L222, line L212 is higher than line L222 in the region where the index value r of the degree of improvement is greater than 0. Therefore, comparing Gumbel EI, indicated by line L212, with EI, indicated by line L222, it can be said that Gumbel EI is more exploratory than EI when the same degree of improvement is obtained.

By determining observation points in an exploratory manner and observing the objective function, the information processing device 100 can preferentially observe observation points with large variations in the estimated value of the objective function, and may thereby reach or approach the global extreme values relatively quickly. According to the information processing device 100, in this respect, it may be possible to efficiently search for argument values that make the objective function value as large as possible or as small as possible.

In addition, by determining observation points in an exploratory manner and observing the objective function, the information processing device 100 preferentially observes observation points with large variations in the estimated value of the objective function, whereby the extent to which the distribution of estimated values of the objective function is narrowed down through observation can be said to be large. Therefore, according to the information processing device 100, it is expected that the possible values of the objective function will be narrowed down at a relatively early stage. According to the information processing device 100, in this respect as well, it may be possible to efficiently search for argument values that make the objective function value as large as possible or as small as possible.

An experimental example of estimating the minimum value of the objective function shall be described.

FIG. 5 shows an example of the Forrester function. The horizontal axis (x-axis) of the graph in FIG. 5 shows argument values, while the vertical axis (y-axis) shows function values. Line L311 represents a one-dimensional Forrester function. The function of line L311 is expressed as in Equation (21).

[Equation 21]

f(x)=(6x−2)²sin (12x−4) (21)

The domain of the function is “0<x<1”. It is also assumed that Gaussian noise of “σ=1.0” is superimposed on the observation.

In the experiment, the objective function was observed for each of the argument values x=0.2 and 0.9 to obtain the observation results at points P21 and P22, and the initial values of the probability distribution of the estimated values of the objective function were set based on the observation results. Points P21 and P22 deviate from line L311 because of noise in the observation results.

Gumbel EI and Gumbel CB, respectively, were used to estimate the minimum value of the objective function. For comparison, the minimum value of the objective function was also estimated using EI and UCB, respectively.

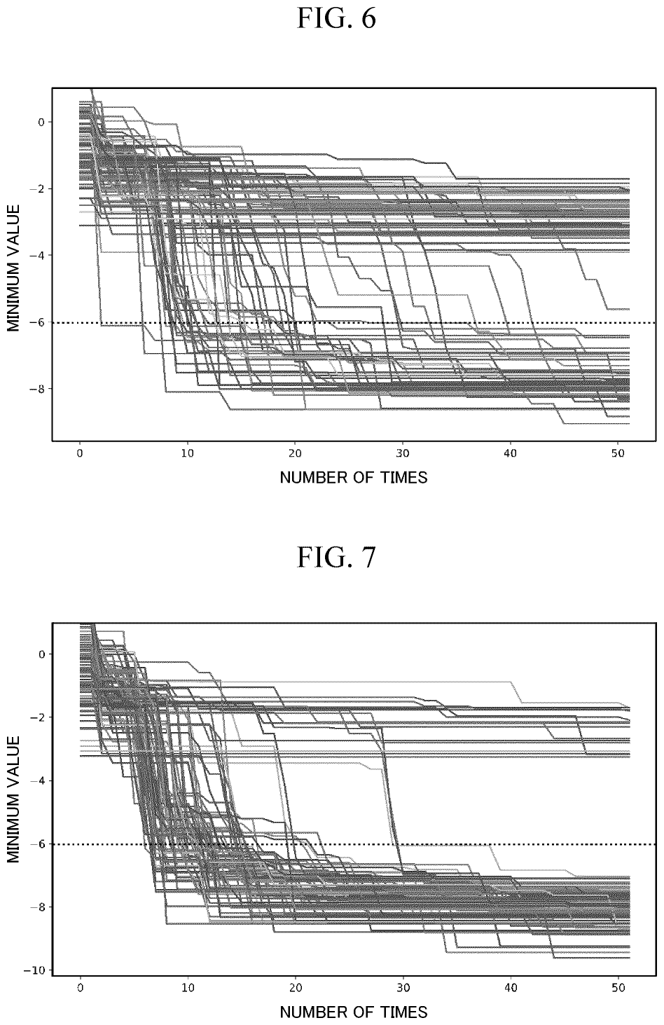

FIG. 6 is a diagram showing an example of the transition of the estimation results of the minimum value of the Forrester function when EI is used.

The horizontal axis of the graph in FIG. 6 shows the number of times the objective function was observed. The vertical axis shows the minimum value of the objective function values obtained from the observation. The graph shows the results of estimating the minimum value 100 times by changing the random number used to generate the noise, and plotting the results of all 100 estimations.

FIG. 7 is a diagram showing an example of the transition of the estimation results of the minimum value of the Forrester function when Gumbel EI is used.

The horizontal axis of the graph in FIG. 7 shows the number of times the objective function was observed. The vertical axis shows the minimum value of the objective function values obtained from the observation. For Gumbel EI, the graph shows the results of estimating the minimum value 100 times by changing the random number used to generate the noise, and plotting the results of all 100 estimations.

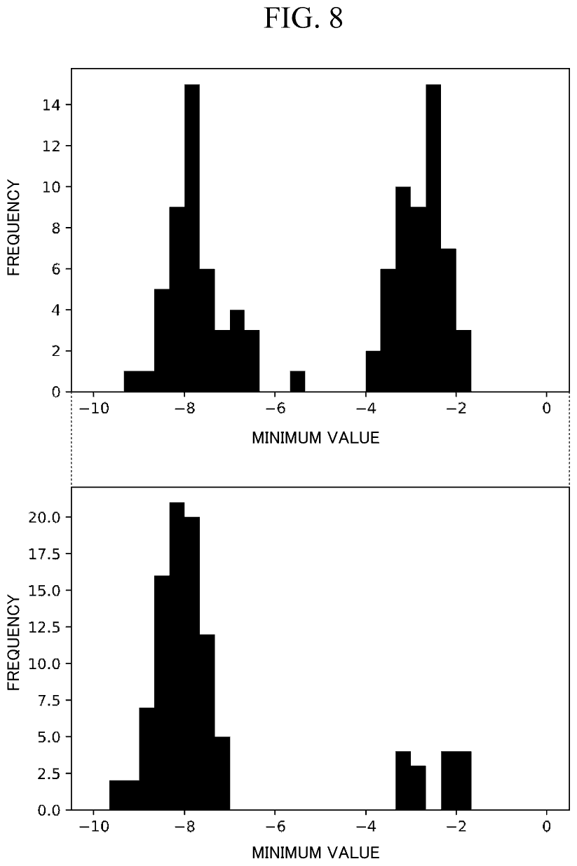

FIG. 8 is a diagram showing an example of the estimation results of the minimum value of the Forrester function for EI and Gumbel EI. FIG. 8 shows an example of aggregation of 100 estimations of the minimum values of the objective function values obtained when 50 observations of the objective function were performed.

The horizontal axis of the graph in FIG. 8 shows the minimum value of the objective function values obtained from the observation. The vertical axis indicates the frequency at which the minimum value shown on the horizontal axis was observed. For the minimum value shown on the horizontal axis, the frequency of the class is shown for each one-third (0.33 . . . ) class width. Therefore, the range from −10 to 0 shown on the horizontal axis is divided into 30 intervals.

The upper graph shows the estimation results using EI, and the lower graph shows the estimation results using Gumbel EI.

Note that while the minimum value of the Forrester function shown in FIG. 5 is about −6 (minus 6), the estimation results shown in FIG. 8 indicate that function values smaller than −6 are observed for both EI and Gumbel EI. This is due to the inclusion of noise in the observation results.

For both EI and Gumbel EI, the estimation results are concentrated around −8 and −3 on the horizontal axis, respectively.

The estimation results near the minimum value of −8 in FIG. 8 are considered to be the estimation results corresponding to the minimum value of the function, shown near the value 0.8 on the horizontal axis of the graph in FIG. 5. This minimum value is approximately −6. The estimation results near the minimum value of −3 in FIG. 8 are considered to be the estimation results corresponding to the minimum value of the function, shown near the value 0.1 on the horizontal axis of the graph in FIG. 5. This minimum value is approximately −1.

Comparing the estimation results using EI shown in the upper graph in FIG. 8 with the estimation results using Gumbel EI shown in the lower graph, it can be observed that, when Gumbel EI is used, the proportion of estimation results near −8 is relatively large, while the proportion of estimation results near −3 is relatively small.

Therefore, it is expected that the use of Gumbel EI is more likely than the use of EI to reach a global optimal solution rather than just a local solution.

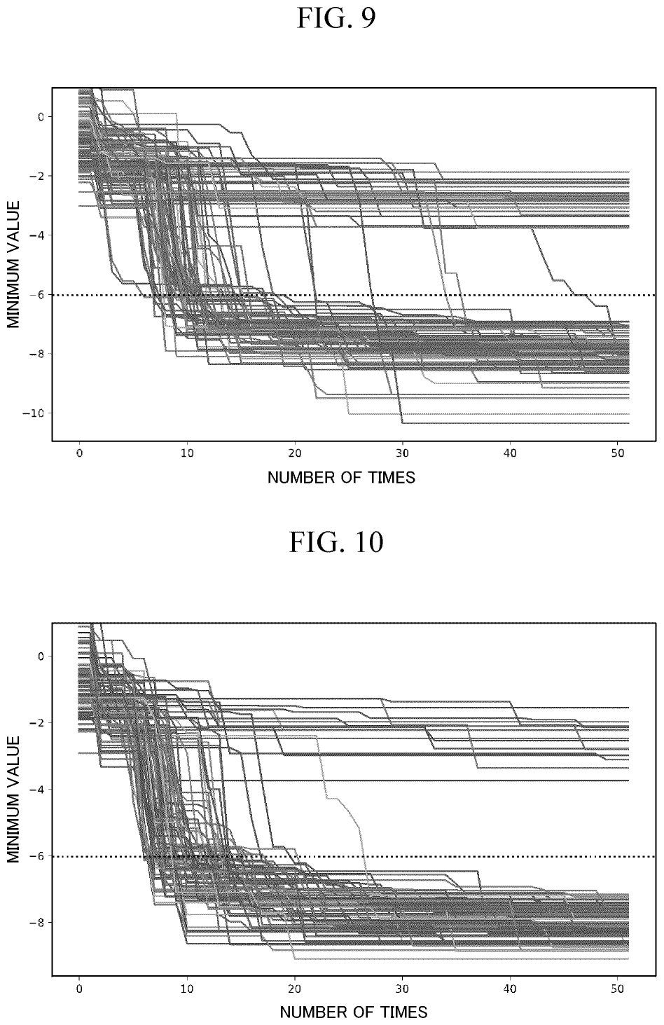

FIG. 9 is a diagram showing an example of the transition of the estimation results of the minimum value of the Forrester function when UCB is used.

The horizontal axis of the graph in FIG. 9 shows the number of times the objective function was observed. The vertical axis shows the minimum value of the objective function values obtained from the observation. For UCB, the graph shows the results of estimating the objective function 100 times by changing the random number used to generate the noise, and plotting the results of all 100 estimations.

FIG. 10 is a diagram showing an example of the transition of the estimation results of the minimum value of the Forrester function when Gumbel CB is used.

The horizontal axis of the graph in FIG. 10 shows the number of times the objective function was observed. The vertical axis shows the minimum value of the objective function values obtained from the observation. For Gumbel CB, the graph shows the results of estimating the objective function 100 times by changing the random number used to generate the noise, and plotting the results of all 100 estimations.

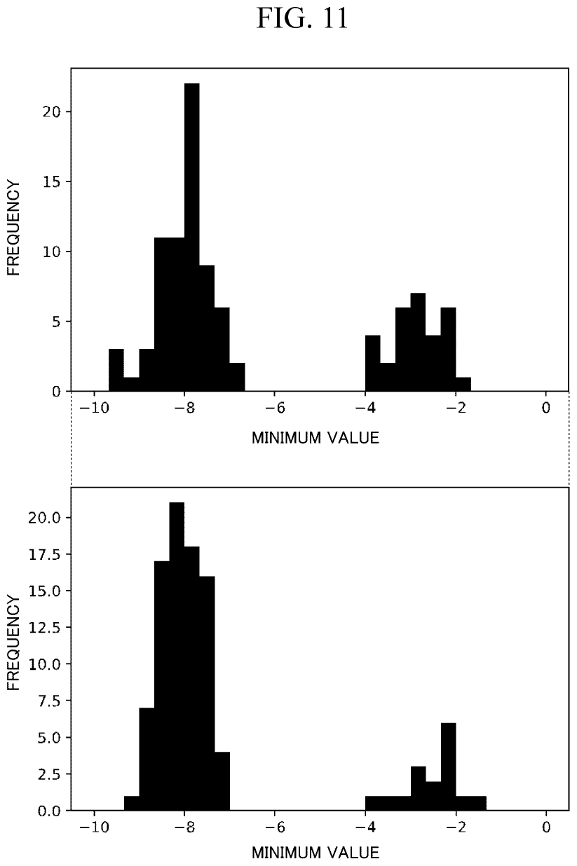

FIG. 11 is a diagram showing an example of the estimation results of the minimum value of the Forrester function for UCB and Gumbel CB. FIG. 11 shows an example of the minimum values of the objective function values obtained from 50 observations of the objective function, aggregated for 100 estimations.

The horizontal axis of the graph in FIG. 11 shows the minimum value of the objective function values obtained from the observation. The vertical axis indicates the frequency at which the minimum value shown on the horizontal axis was observed. For the minimum value shown on the horizontal axis, the frequency of the class is shown for each one-third (0.33 . . . ) class width.

The upper graph shows the estimation results using UCB, and the lower graph shows the estimation results using Gumbel CB.

Note that while the minimum value of the Forrester function shown in FIG. 5 is about −6, the estimation results shown in FIG. 11 indicate that function values smaller than −6 are observed for both UCB and Gumbel CB. This is due to the inclusion of noise in the observation results.

For both UCB and Gumbel CB, the estimation results are concentrated around −8 and −3 on the horizontal axis, respectively.

The estimation results near the minimum value of −8 in FIG. 11 are considered to be the estimation results corresponding to the minimum value of the function, shown near the value 0.8 on the horizontal axis of the graph in FIG. 5. This minimum value is approximately −6. The estimation results near the minimum value of −3 in FIG. 11 are considered to be the estimation results corresponding to the minimum value of the function, shown near the value 0.1 on the horizontal axis of the graph in FIG. 5. This minimum value is approximately −1.

Comparing the estimation results using UCB shown in the upper graph in FIG. 11 with the estimation results using Gumbel CB shown in the lower graph, it can be observed that the proportion of estimation results near −8 is relatively larger when Gumbel CB is used, while the proportion of estimation results near −3 is relatively small. Therefore, it is expected that the use of Gumbel CB is more likely than the use of UCB to reach a global optimal solution rather than just a local solution.

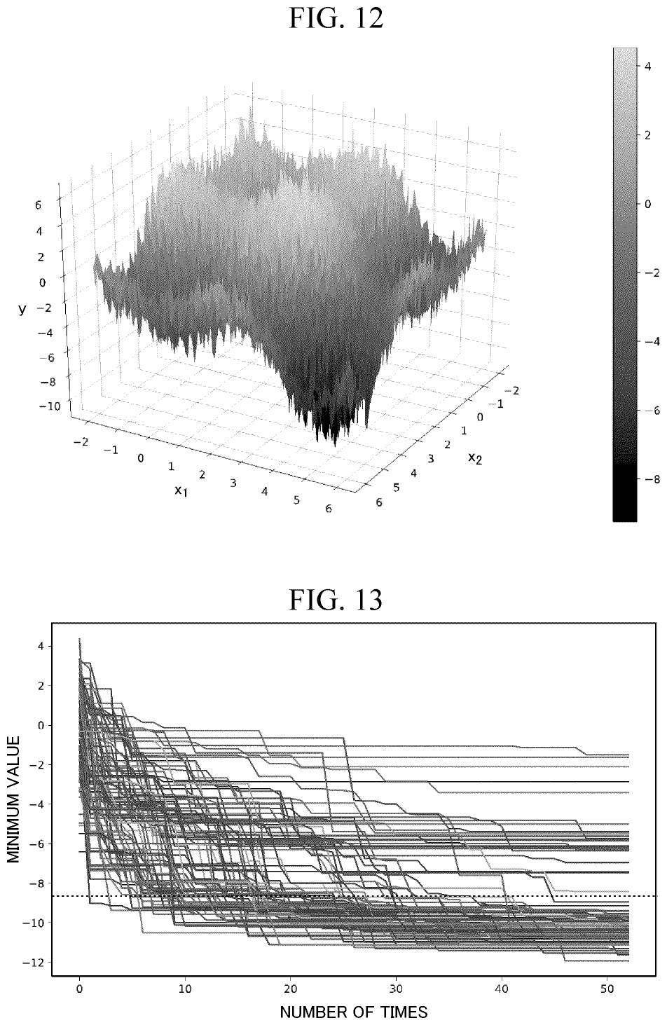

FIG. 12 is a diagram showing an example of an alpine function. The x₁ and x₂ axes of the graphs in FIG. 12 show the argument values, respectively, and they axis shows the function values. The graph in FIG. 12 shows a two-dimensional alpine function.

The graph in FIG. 12 is represented as in Equation (22).

$$\begin{matrix}[ Equation 22 ] & \\ f ( {x}_{1} , {x}_{2} ) = {\sum }_{i = 1}^{2} {x}_{i} sin ( {x}_{i} ) + 0.1 {x}_{i} & ( 22 )\end{matrix}$$

The domain of the function is “−2.0<xᵢ<6.0 (i=1, 2)”.

The minimum value of the function is “f(4.8939, 4.8939)=−8.6482”. This minimum value is located on the front side (the side with larger x₁ and x₂ values) in the graph in FIG. 12.

The minimum values of the function are found on the left side of the graph (the side where x₁ is small and x₂ is large), on the right side (the side where x₁ is large and x₂ is small), and on the far side (the side where both x₁ and x₂ are small). The minimum value on the left side and the minimum value on the right side are relatively small, while the minimum value on the far side is relatively large.

It is also assumed that Gaussian noise of “σ=1.0” is superimposed on the observation.

Gumbel EI and Gumbel CB, respectively, were used to estimate the minimum value of the objective function. For comparison, the minimum value of the objective function was also estimated using EI and UCB, respectively.

FIG. 13 is a diagram showing an example of the transition of the estimation results of the minimum value of the alpine function when EI is used.

The horizontal axis of the graph in FIG. 13 shows the number of times the objective function was observed. The vertical axis shows the minimum value of the objective function values obtained from the observation. The graph shows the results of estimating the minimum value 100 times by changing the random number used to generate the noise, and plotting the results of all 100 estimations.

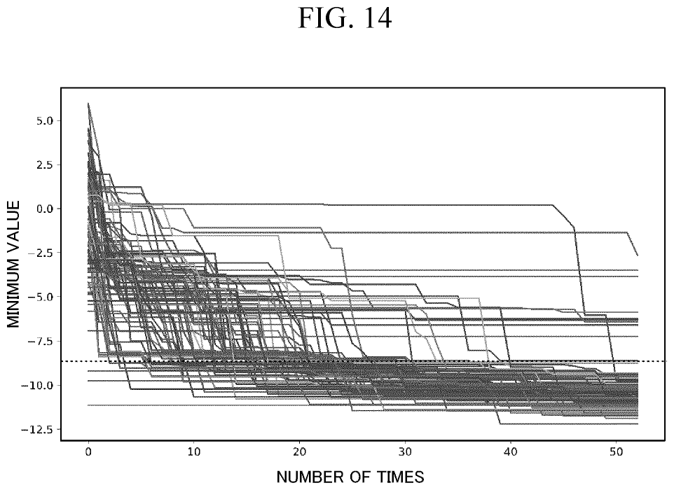

FIG. 14 is a diagram showing an example of the transition of the estimation results of the minimum value of the alpine function when Gumbel EI is used.

The horizontal axis of the graph in FIG. 14 shows the number of times the objective function was observed. The vertical axis shows the minimum value of the objective function values obtained from the observation. For Gumbel EI, the graph shows the results of estimating the minimum value 100 times by changing the random number used to generate the noise, and plotting the results of all 100 estimations.

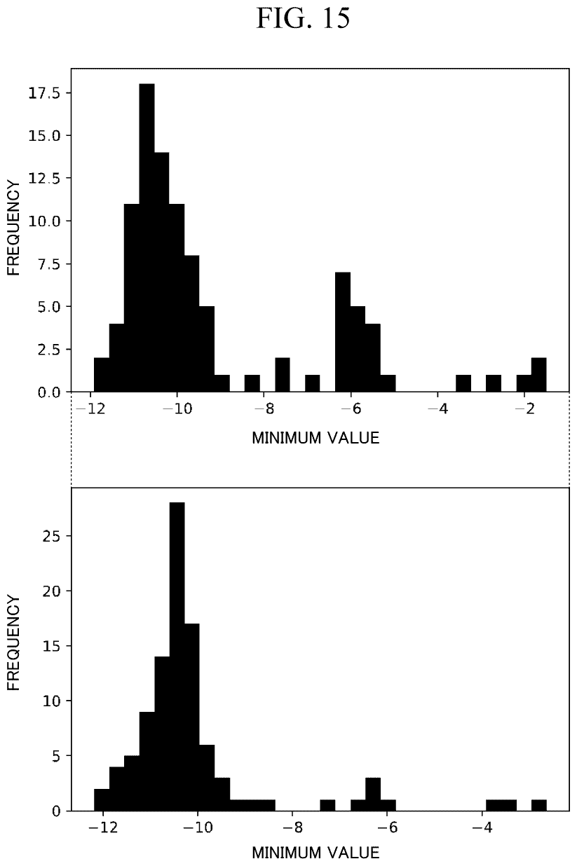

FIG. 15 is a diagram showing an example of the estimation results of the minimum value of the alpine function for EI and Gumbel EI. FIG. 15 shows an example of aggregation of 100 estimations of the minimum values of the objective function values obtained when 50 observations of the objective function were performed.

The horizontal axis of the graph in FIG. 15 shows the minimum value of the objective function values obtained from the observation. The vertical axis indicates the frequency at which the minimum value shown on the horizontal axis was observed. For the minimum value shown on the horizontal axis, the frequency of the class is shown for each one-third (0.33 . . . ) class width.

The upper graph shows the estimation results using EI, and the lower graph shows the estimation results using Gumbel EI.

Note that while the minimum value of the alpine function shown in FIG. 12 is about −8.6, according to the estimation results shown in FIG. 15, function values smaller than −8.6 are observed for both EI and Gumbel EI. This is due to the inclusion of noise in the observation results.

For both EI and Gumbel EI, the estimated results are concentrated around −10, around −6, and around −3 on the horizontal axis, respectively.

The estimation results near the minimum value of −10 in FIG. 15 are considered to be the estimation results corresponding to the minimum value of the function.

The estimation results near the minimum value of −6 in FIG. 15 are considered to be the estimation results corresponding to the left-hand or right-hand minimum value on the left side of the graph in FIG. 12.

The estimation results near the minimum value of −3 in FIG. 15 are considered to be the estimated results corresponding to the minimum value on the far side of the graph in FIG. 12.

Comparing the estimation results using EI shown in the upper graph in FIG. 15 with those using Gumbel EI shown in the lower graph, it can be observed that, when Gumbel EI is used, the proportion of estimation results near −10 is relatively large, while the proportion of estimation results near −6 and the proportion of estimation results near −3 are relatively small.

Therefore, it is expected that the use of Gumbel EI is more likely than the use of EI to reach a global optimal solution rather than just a local solution.

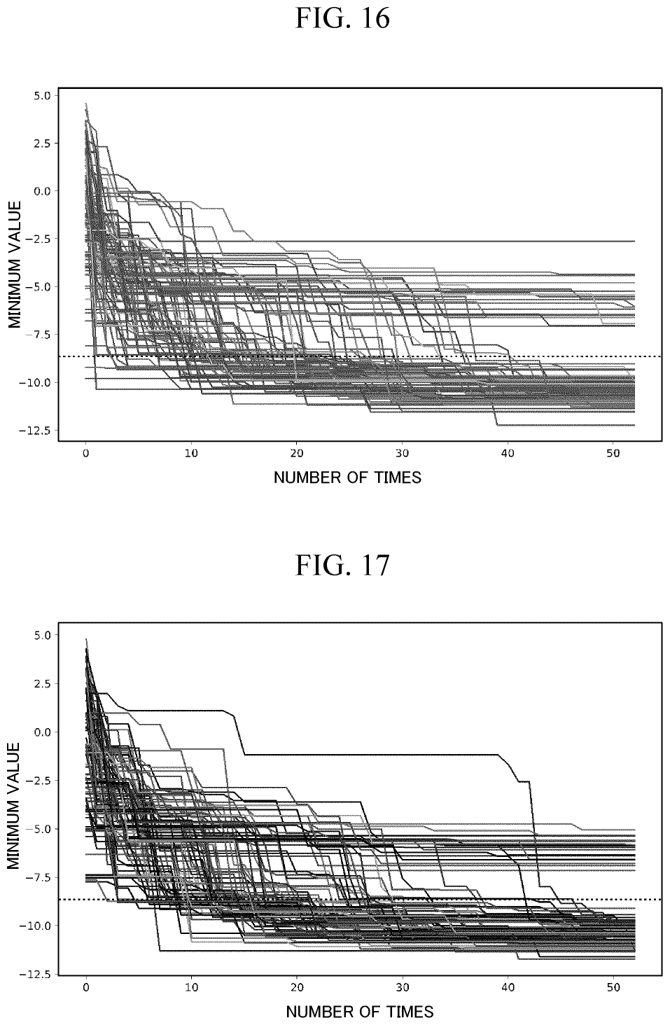

FIG. 16 is a diagram showing an example of the transition of the estimation results of the minimum value of the alpine function when UCB is used.

The horizontal axis of the graph in FIG. 16 shows the number of times the objective function was observed. The vertical axis shows the minimum value of the objective function values obtained from the observation. For UCB, the graph shows the results of estimating the minimum value 100 times by changing the random number used to generate the noise, and plotting the results of all 100 estimations.

FIG. 17 is a diagram showing an example of the transition of the estimation results of the minimum value of the alpine function when Gumbel CB is used.

The horizontal axis of the graph in FIG. 17 shows the number of times the objective function was observed. The vertical axis shows the minimum value of the objective function values obtained from the observation. For Gumbel CB, the graph shows the results of estimating the minimum value 100 times by changing the random number used to generate the noise, and plotting the results of all 100 estimations.

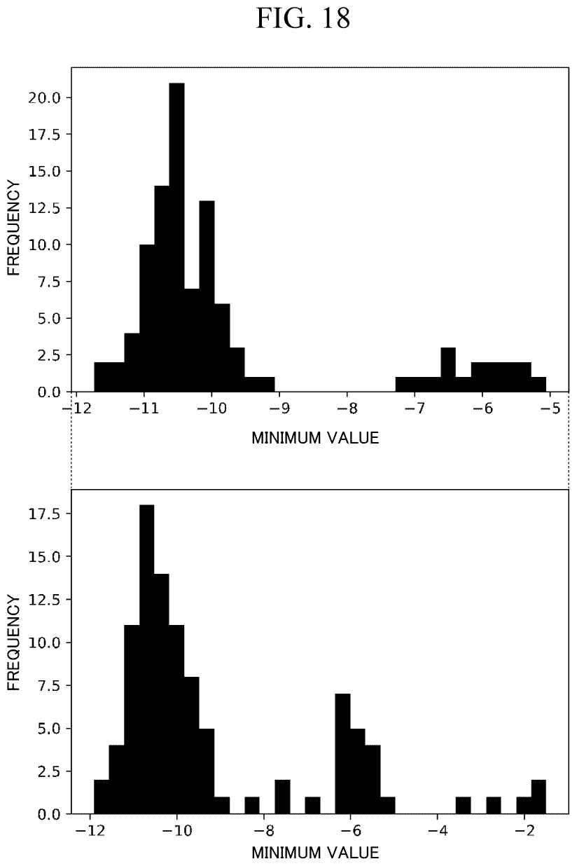

FIG. 18 is a diagram showing an example of the estimation results of the minimum value of the alpine function for UCB and Gumbel CB. FIG. 18 shows an example of aggregation of 100 estimations of the minimum values of the objective function values obtained when 50 observations of the objective function were performed.

The horizontal axis of the graph in FIG. 18 shows the minimum value of the objective function values obtained from the observation. The vertical axis indicates the frequency at which the minimum value shown on the horizontal axis was observed. For the minimum value shown on the horizontal axis, the frequency of the class is shown for each one-third (0.33 . . . ) class width.

The upper graph shows the estimation results using UCB, and the lower graph shows the estimation results using Gumbel CB.

Note that while the minimum value of the alpine function shown in FIG. 18 is about −8.6, according to the estimation results shown in FIG. 18, function values smaller than −8.6 are observed for both UCB and Gumbel CB. This is due to the inclusion of noise in the observation results.

For both UCB and Gumbel CB, the estimation results are concentrated around −10 and −6 on the horizontal axis, respectively. In Gumbel CB, the estimation results are also shown around −3 on the horizontal axis.

The estimation results near the minimum value of −10 in FIG. 18 are considered to be the estimation results corresponding to the minimum value of the function.

The estimation results near the minimum value of −6 in FIG. 18 are considered to be the estimation results corresponding to the left-hand or right-hand minimum value on the left side of the graph in FIG. 12.

The estimation results near the minimum value of −3 in FIG. 18 are considered to be the estimation results corresponding to the minimum value on the far side of the graph in FIG. 12.

Comparing the estimation results using UCB, shown in the upper graph in FIG. 18, with the estimation results using Gumbel CB, shown in the lower graph, the proportion of estimation results around −10 is roughly the same size.

Therefore, it is expected that a global optimal solution rather than just a local solution can be achieved with the use of both Gumbel CB and UCB to the same extent. Thus, when using Gumbel CB, results that are at least as good as or better than those obtained when using UCB are expected to be obtained for a variety of objective functions.

As described above, the probability distribution acquisition unit 191, on the basis of a set including a plurality of samples in which a first value and a second value are associated with each other, acquires a first distribution that is a probability distribution of a first function for calculating the second value from the first value. The function acquisition unit 192, on the basis of a second distribution having an average different from the average of each argument of the first function in the first distribution, acquires a second function for calculating an evaluation value for an argument value of the first function. The argument value determination unit 193, on the basis of the evaluation value calculated by the evaluation function, determines the argument value for sampling a function value of the first function.

This allows the information processing device 100 to determine the next observation point with an emphasis on the possibility of acquiring a global optimal solution rather than using a function based on the probability distribution of the objective function.

The second distribution is an extreme value distribution based on the first distribution.

This allows the information processing device 100 to determine the next observation point with an emphasis on the possibility of acquiring a global optimal solution rather than using a function based on the probability distribution of the objective function. Also, it is expected that the evaluation function becomes a function that is relatively easy to analyze using an exponential function.

The second distribution is a Gumbel distribution based on the first distribution.

This allows the information processing device 100 to determine the next observation point based on a probability distribution that is based on a global extreme value of the objective function, and to determine the next observation point with an emphasis on the possibility of acquiring a global optimal solution rather than using a function based on the probability distribution of the objective function. Also, it is expected that the evaluation function becomes a function that is relatively easy to analyze using an exponential function.

The function acquisition unit 192 also acquires the second function that uses a cumulative distribution function of the second distribution. This allows the information processing device 100 to determine the next observation point with an emphasis on the possibility of acquiring a global optimal solution rather than using a function based on the probability distribution of the objective function. It is also expected that the evaluation function becomes a function that is relatively easy to analyze using a cumulative distribution function.

The function acquisition unit 192 acquires, as the second function, a function obtained by replacing a cumulative density function with a cumulative density function of the second distribution, from a probability-of-improvement acquisition function.

This allows the information processing device 100 to determine the next observation point with an emphasis on the possibility of acquiring a global optimal solution rather than using a function based on the probability distribution of the objective function. It is also expected that the evaluation function will be a relatively easy function to analyze.

The function acquisition unit 192 also acquires the second function, under the second distribution, based on the expected value of an index value of the magnitude of the first function.

This allows the information processing device 100 to determine the next observation point with an emphasis on the possibility of acquiring a global optimal solution rather than using a function based on the probability distribution of the objective function. It is also expected that the evaluation function will be a relatively easy function to analyze.

The function acquisition unit 192 also acquires as the second function a function obtained by replacing the expected value, under a normal distribution, of the index value of the degree of improvement of the estimated value of the objective function with the expected value, under the second distribution, of the index value of the degree of improvement of the estimated value of the first function from an expected improvement acquisition function.

This allows the information processing device 100 to determine the next observation point with an emphasis on the possibility of acquiring a global optimal solution rather than using a function based on the probability distribution of the objective function. It is also expected that the evaluation function will be a relatively easy function to analyze.

The function acquisition unit 192 also acquires a second function that includes a term indicating the average in the Gumbel distribution and a term indicating the variance in the Gumbel distribution.

This allows the information processing device 100 to determine the next observation point with an emphasis on the possibility of acquiring a global optimal solution rather than using a function based on the probability distribution of the objective function. It is also expected that the evaluation function will be a relatively easy function to analyze.

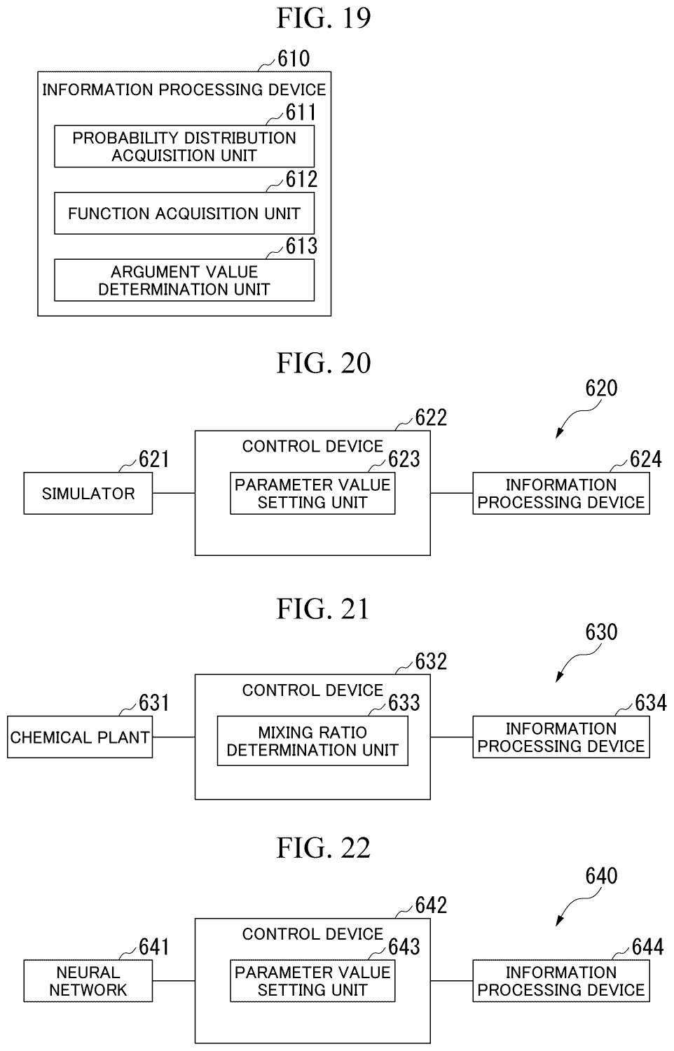

FIG. 19 is a diagram showing a configuration example of the information processing device according to the example embodiment. The information processing device 610 shown in FIG. 19 includes a probability distribution acquisition unit 611, a function acquisition unit 612, and an argument value determination unit 613.

In such a configuration, the probability distribution acquisition unit 611, on the basis of a set including a plurality of samples in which a first value and a second value are associated with each other, acquires a first distribution that is a probability distribution of a first function for calculating the second value from the first value. The function acquisition unit 612, on the basis of a second distribution having an average different from the average of each argument of the first function in the first distribution, acquires a second function for calculating an evaluation value for an argument value of the first function. The argument value determination unit 613, on the basis of the evaluation value by the evaluation function, determines the argument value for sampling a function value of the first function.

This allows the information processing device 610 to determine the next observation point with an emphasis on the possibility of acquiring a global optimal solution rather than using a function based on the probability distribution of the objective function.

The probability distribution acquisition unit 611 corresponds to an example of a probability distribution acquisition means. The function acquisition unit 612 is an example of a function acquisition means. The argument value determination unit 613 corresponds to an example of an argument value determination means. The probability distribution acquisition unit 611 can be realized, for example, using functions such as the probability distribution acquisition unit 191 shown in FIG. 1. The function acquisition unit 612 can be realized, for example, using functions such as the function acquisition unit 192 shown in FIG. 1. The functions of the argument value determination unit 613 can be realized using, for example, the functions of the argument value determination unit 193 shown in FIG. 1.

FIG. 20 is a diagram showing a configuration example of a simulator system according to the example embodiment. A simulator system 620 in FIG. 20 includes a simulator 621, a control device 622, and an information processing device 624. The control device 622 includes a parameter value setting unit 623.

The information processing device 624 estimates the parameter values of the simulator 621 that maximize the evaluation value for the processing of the simulator 621, with the function that receives the input of parameter values of the simulator 621 and outputs the evaluation value for the processing of the simulator 621 serving as the objective function. The information processing device 100 described above may be used as the information processing device 624. Alternatively, the information processing device 610 described above may be used as the information processing device 624.

The parameter value setting unit 623 sets the parameter values of the simulator 621 using the information processing device 624. Specifically, the parameter value setting unit 623 sets the parameter values estimated by the information processing device 624 to the simulator 621.

This allows the information processing device 624 to determine the next observation point with an emphasis on the possibility of acquiring a global optimal solution rather than using a function based on the probability distribution of the objective function.

The configuration of the simulator system 620 is not limited to that shown in FIG. 20. For example, the control device 622 and the information processing device 624 may be configured as a single device.

FIG. 21 is a diagram showing a configuration example of a mixing ratio determination system according to the example embodiment. A mixing ratio determination system 630 shown in FIG. 21 includes a chemical plant 631, a control device 632, and an information processing device 624. The control device 632 includes a mixing ratio determination unit 633.

The information processing device 634 estimates the mixing ratio of materials in the chemical plant 631 that maximizes the evaluation value for the operation result of the chemical plant 631, with a function that receives the input of a mixing ratio of materials of the chemical plant 631 and outputs the evaluation value for the operating result of the chemical plant 631 serving as the objective function. The information processing device 100 described above may be used as the information processing device 634. Alternatively, the information processing device 610 described above may be used as the information processing device 634.

The mixing ratio determination unit 633 determines the mixing ratio of the materials in the chemical plant 631 using the information processing device 624 and sets the amount of each material in the chemical plant 631 based on the determined mixing ratio. Specifically, the mixing ratio determination unit 633 sets the amount of each material in the chemical plant 631 based on the mixing ratio of the materials in the chemical plant 631 estimated by the information processing device 624.

This allows the information processing device 634 to determine the next observation point with an emphasis on the possibility of acquiring a global optimal solution rather than using a function based on the probability distribution of the objective function.

The configuration of the mixing ratio determination system 630 is not limited to that shown in FIG. 21. For example, the control device 632 and the information processing device 634 may be configured as a single device.

FIG. 22 is a diagram that shows a configuration example of a neural network system according to the example embodiment. A neural network system 640 shown in FIG. 22 includes a neural network (a recording medium that stores neural networks) 641, a control device 642, and an information processing device 644. The control device 642 includes a parameter value setting unit 643.

The information processing device 644 estimates the parameter values of the neural network 641 that maximize the evaluation value for the processing of the neural network 641, with the function that receives the input of parameter values of the neural network 641 and outputs the evaluation value for the processing of the neural network 641 serving as the objective function. The information processing device 100 described above may be used as the information processing device 644. Alternatively, the information processing device 610 described above may be used as the information processing device 624.

The parameter value setting unit 643 sets the parameter values of the neural network 641 using the information processing device 644. Specifically, the parameter value setting unit 643 sets the parameter values estimated by the information processing device 644 to the neural network 641.

This allows the information processing device 644 to determine the next observation point with an emphasis on the possibility of acquiring a global optimal solution rather than using a function based on the probability distribution of the objective function.

The configuration of the neural network system 640 is not limited to the configuration shown in FIG. 22. For example, the control device 642 and the information processing device 644 may be configured as a single device.

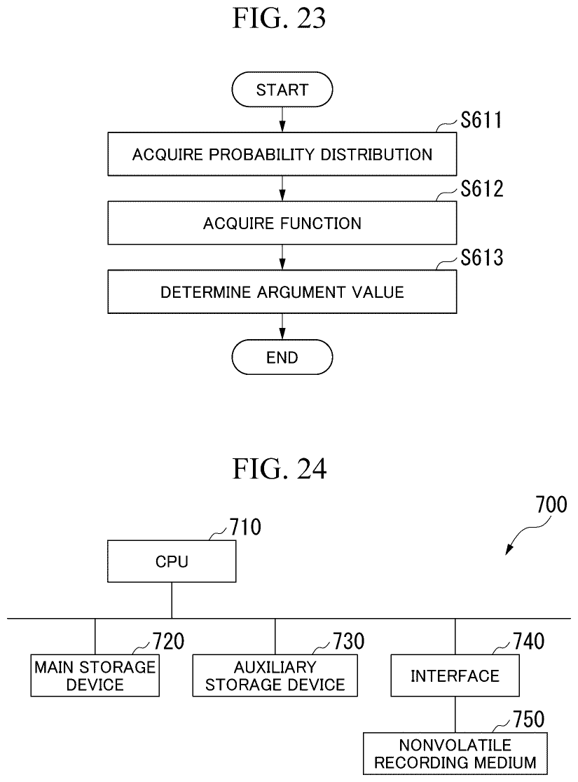

FIG. 23 is a flowchart showing an example of the processing procedure in the argument value determination method according to the example embodiment. The argument value determination method shown in FIG. 23 includes acquiring a probability distribution (Step S611), acquiring a function (Step S612), and determining an argument value (Step S613).

In acquiring a probability distribution (Step S611), a first distribution that is a probability distribution of a first function for calculating the second value from the first value is acquired on the basis of a set including a plurality of samples in which a first value and a second value are associated with each other.

In acquiring a function (Step S612), on the basis of a second distribution having an average different from the average of each argument of the first function in the first distribution, a second function is acquired for calculating an evaluation value indicating the priority of an argument of the first function.

In determining an argument value (Step S613), on the basis of the evaluation value by the evaluation function, an argument value for sampling a function value of the first function is determined.

According to the argument value determination method shown in FIG. 23, it is possible to determine the next observation point with an emphasis on the possibility of acquiring a global optimal solution rather than using a function based on the probability distribution of the objective function.

FIG. 24 is a schematic block diagram showing the configuration of a computer for at least one example embodiment.

In the configuration shown in FIG. 24, a computer 700 includes a CPU 710, a main storage device 720, an auxiliary storage device 730, an interface 740, and a nonvolatile recording medium 750.

Any one or more of the above information processing devices 100, 610, 624, 634 and 644, control devices 622, 632 and 642, or any part thereof may be implemented in the computer 700. In that case, the operations of each of the above-mentioned processing units are stored in the auxiliary storage device 730 in the form of a program. The CPU 710 reads the program from the auxiliary storage device 730, deploys the program in the main storage device 720, and executes the above processing according to the program. The CPU 710 also reserves a storage area in the main storage device 720 corresponding to each of the above-mentioned storage units according to the program. Communication between each device and other devices is performed by the interface 740 having a communication function and performing communication according to the control of the CPU 710. The interface 740 also has a port for the nonvolatile recording medium 750 and reads information from and writes information to the nonvolatile recording medium 750.

When the information processing device 100 is implemented in a computer 700, the operation of the control unit 190 and its various parts is stored in the auxiliary storage device 730 in the form of a program. The CPU 710 reads the program from the auxiliary storage device 730, deploys the program in the main storage device 720, and executes the above processing according to the program.

The CPU 710 also reserves a storage area in the main storage device 720 corresponding to the storage unit 180 according to the program.

Communication with other devices by the communication unit 110 is performed by the interface 740, which has communication functions and operates according to the control of the CPU 710.

The display by the display unit 120 is performed by the interface 740 having a display device and displaying various images according to the control of the CPU 710.

Reception of a user operation by the operation input unit 130 is performed by the interface 740 having input devices such as a keyboard and a mouse, for example, to receive user operations and output information indicating received user operations to the CPU 710.

When the information processing device 610 is implemented in the computer 700, the operations of the probability distribution acquisition unit 611, the function acquisition unit 612, and the argument value determination unit 613 are stored in the auxiliary storage device 730 in the form of programs. The CPU 710 reads the program from the auxiliary storage device 730, deploys the program in the main storage device 720, and executes the above processing according to the program.

The CPU 710 also reserves a storage area in the main storage device 720 for the information processing device 610 to perform processing according to the program.

Communication between the information processing device 610 and other devices is performed by the interface 740, which has a communication function and operates according to the control of the CPU 710.

The interaction between the information processing device 610 and the user is performed by the interface 740, which has a display and input device and operates according to the control of the CPU 710.

When the information processing device 624 is implemented in the computer 700, the operation of the information processing device 624 is stored in the auxiliary storage device 730 in the form of a program. The CPU 710 reads the program from the auxiliary storage device 730, deploys the program in the main storage device 720, and executes the above processing according to the program.

The CPU 710 also reserves a storage area in the main storage device 720 for the information processing device 624 to perform processing according to the program.

Communication between the information processing device 624 and other devices is performed by the interface 740, which has a communication function and operates according to the control of the CPU 710.

The interaction between the information processing device 624 and the user is performed by the interface 740, which has a display device and input device and operates according to the control of the CPU 710.

When the information processing device 634 is implemented in the computer 700, the operation of the information processing device 634 is stored in the auxiliary storage device 730 in the form of a program. The CPU 710 reads the program from the auxiliary storage device 730, deploys the program in the main storage device 720, and executes the above processing according to the program.

The CPU 710 also reserves a storage area in the main storage device 720 for the information processing device 634 to perform processing according to the program.

Communication between the information processing device 634 and other devices is performed by the interface 740, which has a communication function and operates according to the control of the CPU 710.

The interaction between the information processing device 634 and the user is performed by the interface 740, which has a display device and input device and operates according to the control of the CPU 710.

When the information processing device 644 is implemented in the computer 700, the operation of the information processing device 644 is stored in the auxiliary storage device 730 in the form of a program. The CPU 710 reads the program from the auxiliary storage device 730, deploys the program in the main storage device 720, and executes the above processing according to the program.

The CPU 710 also reserves a storage area in the main storage device 720 for the information processing device 644 to perform processing according to the program.

Communication between the information processing device 644 and other devices is performed by the interface 740, which has a communication function and operates according to the control of the CPU 710.

The interaction between the information processing device 644 and the user is performed by the interface 740, which has a display device and input device and operates according to the control of the CPU 710.

When the control device 622 is implemented in the computer 700, the operation of the parameter value setting unit 623 is stored in the auxiliary storage device 730 in the form of a program. The CPU 710 reads the program from the auxiliary storage device 730, deploys the program in the main storage device 720, and executes the above processing according to the program.

The CPU 710 also reserves a storage area in the main storage device 720 for the control device 622 to perform processing according to the program.

Communication between the control device 622 and other devices is performed by the interface 740, which has a communication function and operates according to the control of the CPU 710.

The interaction between the control device 622 and the user is performed by the interface 740, which has a display device and input device and operates according to the control of the CPU 710.

When the control device 632 is implemented in the computer 700, the operation of the mixing ratio determination unit 633 is stored in the auxiliary storage device 730 in the form of a program. The CPU 710 reads the program from the auxiliary storage device 730, deploys the program in the main storage device 720, and executes the above processing according to the program.

The CPU 710 also reserves a storage area in the main storage device 720 for the control device 632 to perform processing according to the program.

Communication between the control device 632 and other devices is performed by the interface 740, which has a communication function and operates according to the control of the CPU 710.

The interaction between the control device 632 and the user is performed by the interface 740, which has a display device and input device and operates according to the control of the CPU 710.

When the control device 642 is implemented in the computer 700, the operation of the parameter value setting unit 643 is stored in the auxiliary storage device 730 in the form of a program. The CPU 710 reads the program from the auxiliary storage device 730, deploys the program in the main storage device 720, and executes the above processing according to the program.

The CPU 710 also reserves a storage area in the main storage device 720 for the control device 642 to perform processing according to the program.

Communication between the control device 642 and other devices is performed by the interface 740, which has a communication function and operates according to the control of the CPU 710.

The interaction between the control device 642 and the user is performed by the interface 740, which has a display device and input device and operates according to the control of the CPU 710.

Any one or more of the above programs may be recorded on the nonvolatile recording medium 750. In this case, the interface 740 may read the program from the nonvolatile recording medium 750. The CPU 710 may then directly execute the program read by the interface 740, or it may be stored once in the main storage device 720 or the auxiliary storage device 730 and then executed.

A program for executing all or part of the processing performed by the information processing device 100, 610, 624, 634, and 644 and the control device 622, 632, and 642 may be recorded on a computer-readable recording medium, and the program recorded on this recording medium may be read into the computer system and executed to perform the processing of each part. The term “computer system” here shall include an operating system and hardware such as peripherals.

In addition, “computer-readable recording medium” means a portable medium such as a flexible disk, magneto-optical disk, ROM (Read Only Memory), CD-ROM (Compact Disc Read Only Memory), or other storage device such as a hard disk built into a computer system. The aforementioned program may be used to realize some of the aforementioned functions, and may also be used to realize the aforementioned functions in combination with a program already recorded in the computer system.

While the above example embodiments of this invention have been described in detail with reference to the drawings, specific configurations are not limited to these example embodiments, and designs are also included to the extent that they do not depart from the gist of this invention.

Some or all of the above example embodiments may also be described as, but not limited to, the following supplementary notes.

### Supplementary Note 1

An information processing device comprising:
a probability distribution acquisition means that acquires, based on a set including a plurality of samples in which a first value and a second value are associated with each other, a first distribution that is a probability distribution of a first function for calculating the second value from the first value;
a function acquisition means that acquires, based on a second distribution having an average different from an average of each argument of the first function in the first distribution, a second function for calculating an evaluation value for an argument value of the first function; and
an argument value determination means that determines, based on the evaluation value by the second function, an argument value for sampling a function value of the first function.

### Supplementary Note 2

The information processing device according to supplementary note 1, wherein the second distribution is an extreme value distribution based on the first distribution.

### Supplementary Note 3

The information processing device according to supplementary note 2, wherein the second distribution is a Gumbel d istribution based on the first distribution.

### Supplementary Note 4

The information processing device according to any one of supplementary notes 1 to 3, wherein the function acquisition means acquires the second function that uses a cumulative distribution function of the second distribution.

### Supplementary Note 5

The information processing device according to supplementary note 4, wherein the function acquisition means acquires, as the second function, a function obtained by replacing a cumulative density function with a cumulative density function of the second distribution as the second function from a probability-of-improvement acquisition function.

### Supplementary Note 6

The information processing device according to any one of supplementary notes 1 to 3, wherein the function acquisition means acquires the second function based on an expected value, under the second distribution, of an index value of magnitude of the first function.

### Supplementary Note 7

The information processing device according to supplementary note 6, wherein the function acquisition means acquires as the second function a function obtained by replacing an expected value, under a normal distribution, of the index value of a degree of improvement of an estimated value of an objective function with an expected value, under the second distribution, of an index value of a degree of improvement of an estimated value of the first function from an expected improvement acquisition function.

### Supplementary Note 8

The information processing device according to supplementary note 3, wherein the function acquisition means acquires the second function that includes a term indicating an average in the Gumbel distribution and a term indicating a variance in the Gumbel distribution.

### Supplementary Note 9

A simulator system comprising:
the information processing device according to any one of supplementary notes 1 to 8;
a simulator; and
a parameter value setting means that sets parameter values of the simulator using the information processing device.

### Supplementary Note 10

A mixing ratio determination system comprising:
the information processing device according to any one of supplementary notes 1 to 8; and
a mixing ratio determination means that determines a candidate mixing ratio of materials in a chemical plant using the information processing device.

### Supplementary Note 11

A neural network system comprising:
the information processing device according to any one of supplementary notes 1 to 8;
a neural network; and
a parameter value setting means that sets a parameter value of the neural network using the information processing device.

### Supplementary Note 12

An argument value determination method executed by the computer, comprising:
acquiring, based on a set including a plurality of samples in which a first value and a second value are associated with each other, a first distribution that is a probability distribution of a first function for calculating the second value from the first value;
acquiring, based on a second distribution having an average different from an average of each argument of the first function in the first distribution, a second function for calculating an evaluation value for an argument value of the first function; and
determining, based on the evaluation value by the second function, an argument value for sampling a function value of the first function.

### Supplementary Note 13

A recording medium that stores a program for causing a computer to execute:
acquiring, based on a set including a plurality of samples in which a first value and a second value are associated with each other, a first distribution that is a probability distribution of a first function for calculating the second value from the first value;
acquiring, based on a second distribution having an average different from an average of each argument of the first function in the first distribution, a second function for calculating an evaluation value for an argument value of the first function; and
determining, based on the evaluation value by the second function, an argument value for sampling a function value of the first function.

Priority is claimed on Japanese Patent Application No. 2021-016101, filed Feb. 3, 2021, the content of which is incorporated herein by reference.

### Industrial Applicability

The invention may be applied to an information processing device, a simulator system, a neural network system, an argument value determination method, and a recording medium.

### Description of Reference Symbols

10 Observation system
100, 610, 624, 634, 644 Information processing device
110 Communication unit
120 Display unit
130 Operation input unit
180 Storage unit
190 Control unit
191, 611 Probability distribution acquisition unit
192, 612 Function acquisition unit
193, 613 Argument value determination unit
194 Function value acquisition unit
195 Termination processing unit
200 Observation target
620 Simulator system
621 Simulator
622, 632, 642 Control device
623, 643 Parameter value setting unit
630 Mixing ratio determination system
631 Chemical plant
633 Mixing ratio determination unit
640 Neural network system
641 Neural network

What is claimed is:

1. An information processing device comprising:
a memory configured to store instructions; and
a processor configured to execute the instructions to:
acquire, based on a set including a plurality of samples in which a first value and a second value are associated with each other, a first distribution that is a probability distribution of a first function for calculating the second value from the first value;
acquire, based on a second distribution having an average different from an average of each argument of the first function in the first distribution, a second function for calculating an evaluation value for an argument value of the first function; and
determine, based on the evaluation value by the second function, an argument value for sampling a function value of the first function.

2. The information processing device according to claim 1, wherein the second distribution is an extreme value distribution based on the first distribution.

3. The information processing device according to claim 2, wherein the second distribution is a Gumbel distribution based on the first distribution.

4. The information processing device according to claim 1, wherein the processor is configured to execute the instructions to acquire the second function that uses a cumulative distribution function of the second distribution.

5. The information processing device according to claim 4, wherein the processor is configured to execute the instructions to acquire, as the second function, a function obtained by replacing a cumulative density function with a cumulative density function of the second distribution as the second function from a probability-of-improvement acquisition function.

6. The information processing device according to claim 1, wherein the processor is configured to execute the instructions to acquire the second function based on an expected value, under the second distribution, of an index value of magnitude of the first function.

7. The information processing device according to claim 6, wherein the processor is configured to execute the instructions to acquire as the second function a function obtained by replacing an expected value, under a normal distribution, of the index value of a degree of improvement of an estimated value of an objective function with an expected value, under the second distribution, of an index value of a degree of improvement of an estimated value of the first function from an expected improvement acquisition function.

8. The information processing device according to claim 3, wherein the processor is configured to execute the instructions to acquire the second function that includes a term indicating an average in the Gumbel distribution and a term indicating a variance in the Gumbel distribution.

9. A simulator system comprising:
the information processing device according to claim 1; and
a simulator,
wherein the processor is configured to execute the instructions to set parameter values of the simulator using the information processing device.

10. A mixing ratio determination system comprising:
the information processing device according to claim 1,
wherein the processor is configured to execute the instructions to determine a candidate mixing ratio of materials in a chemical plant using the information processing device.

11. A neural network system comprising:
the information processing device according to claim 1; and
a neural network,
wherein the processor is configured to execute the instructions to set a parameter value of the neural network using the information processing device.

12. An argument value determination method executed by the computer, comprising:
acquiring, based on a set including a plurality of samples in which a first value and a second value are associated with each other, a first distribution that is a probability distribution of a first function for calculating the second value from the first value;
acquiring, based on a second distribution having an average different from an average of each argument of the first function in the first distribution, a second function for calculating an evaluation value for an argument value of the first function; and
determining, based on the evaluation value by the second function, an argument value for sampling a function value of the first function.

13. A non-transitory recording medium that stores a program for causing a computer to execute:
acquiring, based on a set including a plurality of samples in which a first value and a second value are associated with each other, a first distribution that is a probability distribution of a first function for calculating the second value from the first value;
acquiring, based on a second distribution having an average different from an average of each argument of the first function in the first distribution, a second function for calculating an evaluation value for an argument value of the first function; and
determining, based on the evaluation value by the second function, an argument value for sampling a function value of the first function.
